(19) United States
(12) Patent Application Publication
(10) Pub. No.: US 2021/0152251 A1
(43) Pub. Date: May 20, 2021

(54) OPTICAL-BASED TERAHERTZ WIRELESS SIGNAL TRANSMITTER AND WIRELESS SIGNAL RECEIVER

(71) Applicant: Electronics and Telecommunications Research Institute, Daejeon (KR)

(72) Inventors: Sang Rok MOON, Daejeon (KR); Joonyoung KIM, Daejeon (KR); Sun Hyok CHANG, Daejeon (KR)

(21) Appl. No.: 17/097,212

(22) Filed: Nov. 13, 2020

(30) Foreign Application Priority Data
Nov. 14, 2019 (KR) 10-2019-0145611

(51) Int. Cl. H04B 10/50; H04B 10/572; H01S 3/30; H01S 3/067

(52) U.S. Cl. CPC H04B 10/506; H04B 10/572; H01S 3/06754; H01S 3/302; H04B 10/505

(57) ABSTRACT

A wireless signal transmitter and a wireless signal receiver are provided. The wireless signal transmitter includes an optical signal generation region that generates excitation light by beating two optical signals that have different wavelengths and that are output through different laser diodes, and a wireless signal generation region that modulates the excitation light output from the optical signal generation region into a wireless signal with a carrier frequency of a terahertz band, using a photomixer. The optical signal generation region and the wireless signal generation region may be connected by a multimode optical fiber to reduce a nonlinear effect occurring in an optical fiber. Also, the wireless signal receiver includes a signal processor, for example, an equalizer, for compensating for a modal dispersion, and may compensate for a modal dispersion caused by the multimode optical fiber used in the wireless signal transmitter.

### CROSS-REFERENCE TO RELATED APPLICATION

This application claims the benefit of Korean Patent Application No. 10-2019-0145611 filed on Nov. 14, 2019, in the Korean Intellectual Property Office.

### BACKGROUND

### 1. Technical Field

One or more example embodiments relate to a wireless signal transmitter and a wireless signal receiver, and more particularly, to an apparatus for transmitting and receiving a wireless signal of an optical-based terahertz band.

### 2. Description of Related Art

In wireless communication, a terahertz band of carrier frequencies of 0.3 terahertz (THz) to 3 THz is considered to be unsuitable for communication due to a difficulty in generating a wireless signal having a carrier frequency in the terahertz band and transmitting and receiving the wireless signal, and due to an issue of a straightness of a wireless signal of the terahertz band. However, recently, a possibility of communication in the terahertz band is receiving attention, with great development in technologies of manufacturing a device for generating and reconstructing a wireless signal of the terahertz band and development in a method to solve a straightness of a wireless signal of the terahertz band such as beamforming.

In a structure for transmitting and receiving a wireless signal of an optical-based terahertz band, a high-speed signal may be modulated with a high quality using an existing optical technology. However, the structure has disadvantages in the physical size, complexity, and power consumption of a wireless signal transmitter.

### SUMMARY OF THE INVENTION

Example embodiments provide an apparatus for transmitting and receiving a wireless signal of an optical-based terahertz band, and more particularly, provide a wireless signal transmitter for reducing a nonlinear effect occurring in an optical fiber by connecting, through a multimode optical fiber, an optical signal generation region that generates a beating signal by overlapping of two optical signals having different wavelengths and a wireless signal generation region that modulates the generated beating signal into a wireless signal having a carrier frequency of a terahertz band.

Also, example embodiments provide a wireless signal receiver including a signal processor for compensating for a modal dispersion caused by the multimode optical fiber.

According to an aspect, there is provided a wireless signal transmitter including two laser diodes configured to output two optical signals having different wavelengths, and a photomixer configured to modulate a beating signal generated by overlapping of the two optical signals output from the two laser diodes in a space into a wireless signal with a carrier frequency of a terahertz band, wherein an optical signal generation region including the two laser diodes and a wireless signal generation region including the photomixer are connected by a multimode optical fiber.

The optical signal generation region may further include an optical modulator configured to modulate at least one of the two optical signals that have different wavelengths and that are output from the two laser diodes and configured to input data.

The optical signal generation region may further include an optical amplifier configured to amplify the generated beating signal.

According to another aspect, there is provided a wireless signal transmitter including a laser diode configured to output an optical signal having a wavelength different from a wavelength of an optical signal received from the outside, and a photomixer configured to modulate a beating signal generated by overlapping of the optical signal output from the laser diode and the optical signal received from the outside in a space into a wireless signal with a carrier frequency of a terahertz band, wherein an optical signal generation region including the laser diode and a wireless signal generation region including the photomixer are connected by a multimode optical fiber.

The optical signal generation region may further include an optical modulator configured to modulate at least one of the optical signal output from the laser diode and the optical signal received from the outside, and configured to input data.

The optical signal generation region may further include an optical amplifier configured to amplify the generated beating signal.

According to another aspect, there is provided a wireless signal receiver including a mixer configured to frequency-convert a wireless signal with a carrier frequency of a terahertz band into a baseband signal using a local oscillator (LO) signal received from a LO, and a signal processor configured to compensate for a modal dispersion of the wireless signal frequency-converted into the baseband signal, wherein the modal dispersion is caused by a multimode optical fiber connected between an optical signal generation region and a wireless signal generation region of a wireless signal transmitter configured to output the wireless signal with the carrier frequency of the terahertz band.

The signal processor may include an equalizer configured to compensate for the modal dispersion of the wireless signal frequency-converted into the baseband signal.

### ADVANTAGEOUS EFFECTS

According to example embodiments, an optical signal generation region that generates a beating signal by overlapping of two optical signals having different wavelengths, and a wireless signal generation region that modulates the generated beating signal into a wireless signal having a carrier frequency of a terahertz band may be connected through a multimode optical fiber, and thus it is possible to reduce a nonlinear effect occurring in an optical fiber.

Also, according to example embodiments, a signal processor for compensating for a modal dispersion may be disposed in a wireless signal receiver, and thus it is possible to compensate for a modal dispersion caused by a multimode optical fiber used in a wireless signal transmitter.

### BRIEF DESCRIPTION OF DRAWINGS

FIG. 1 is a diagram schematically illustrating a transmission and reception system for transmitting and receiving a wireless signal of an optical-based terahertz band according to an example embodiment.

FIG. 2 is a diagram illustrating a configuration in which an optical signal generation region is centralized in a wireless signal transmitter for transmitting a wireless signal of a terahertz band according to an example embodiment.

FIG. 3 is a diagram illustrating a transmission and reception system for transmitting and receiving a wireless signal of a terahertz band, including a multimode optical fiber and a signal processor for compensating for a modal dispersion according to an example embodiment.

FIG. 4 is a diagram illustrating a transmission and reception system for transmitting and receiving a wireless signal of a terahertz band, connected to an external optical communication system according to an example embodiment.

### DETAILED DESCRIPTION OF THE INVENTION

Hereinafter, example embodiments will be described in detail with reference to the accompanying drawings.

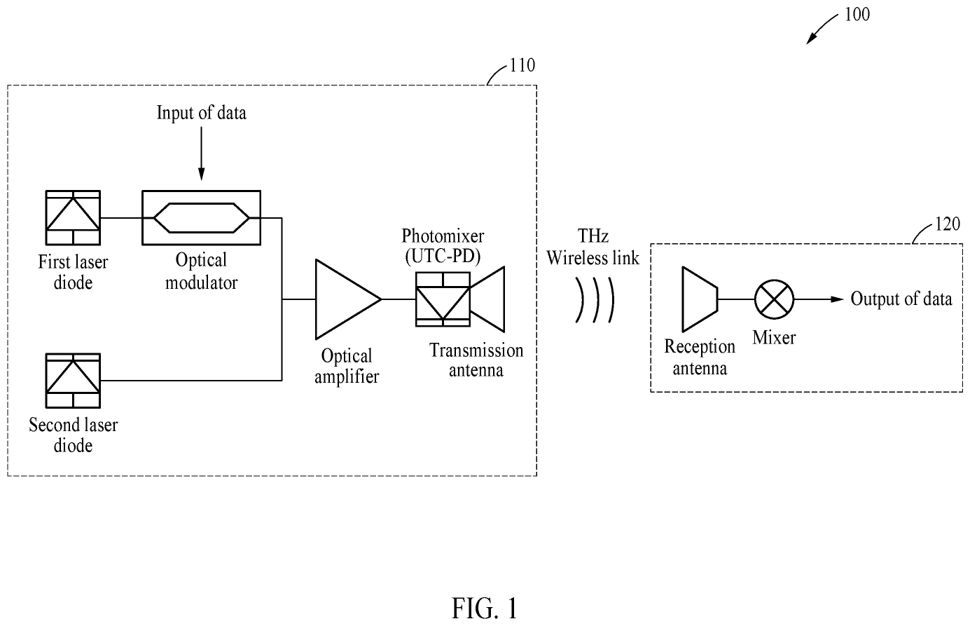

FIG. 1 is a diagram schematically illustrating a transmission and reception system for transmitting and receiving a wireless signal of an optical-based terahertz band according to an example embodiment.

Referring to FIG. 1, a transmission and reception system 100 for transmitting and receiving a wireless signal of an optical-based terahertz band may be broadly divided into a wireless signal transmitter 110 and a wireless signal receiver 120. The wireless signal transmitter 110 may generate a wireless signal of a terahertz band by beating two optical signals that have different wavelengths and that are output through different laser diodes.

Specifically, the wireless signal transmitter 110 may output two optical signals spaced apart by a predetermined carrier frequency of a specific terahertz band through a first laser diode and a second laser diode. Also, the wireless signal transmitter 110 may generate a beating signal with a carrier frequency component of the terahertz band by beating the output optical signals. Here, a frequency of the beating signal may correspond to a difference between wavelengths of two optical signals that overlap (i.e., are beaten) in a space. The wireless signal transmitter 110 may modulate the beating signal using a photomixer and may output a wireless signal of the terahertz band.

Here, the photomixer of the wireless signal transmitter 110 may include, for example, a uni-traveling carrier photodiode (UTC-PD) with an extremely wide bandwidth. Here, the UTC-PD as the photomixer may have a relatively low sensitivity, instead of having an extremely wide bandwidth, and accordingly an input of relatively high optical power may be required. Thus, the wireless signal transmitter 110 may sufficiently amplify a light intensity of the beating signal using an optical amplifier, to input a beating signal having relatively high optical power to the UTC-PD.

The wireless signal transmitter 110 may modulate at least one of the two optical signals output through the different laser diodes using an optical modulator, to input data that is to be transmitted at a carrier frequency of a terahertz band. The wireless signal receiver 120 may down-convert the wireless signal of the terahertz band received from the wireless signal transmitter 110 into a baseband signal using a mixer, to output data carried on the carrier frequency of the terahertz band.

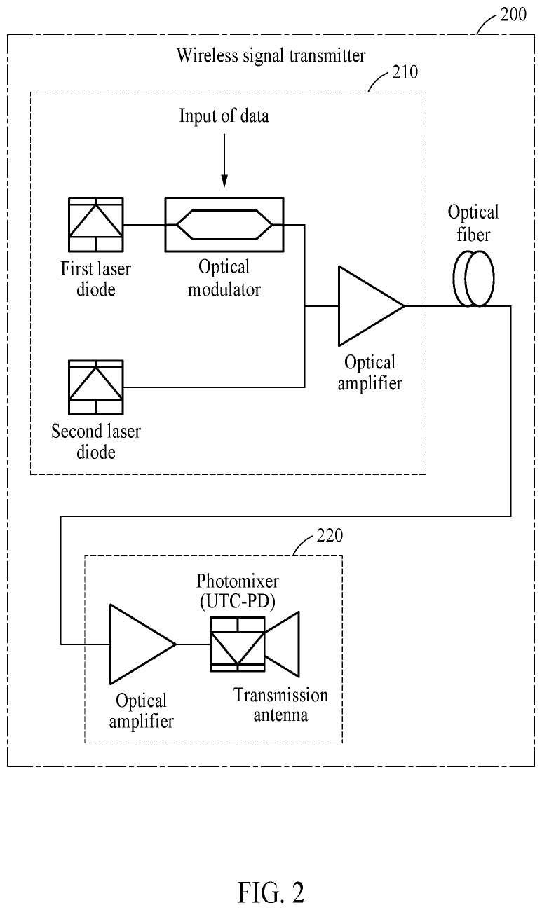

FIG. 2 is a diagram illustrating a configuration in which an optical signal generation region is centralized in a wireless signal transmitter for transmitting a wireless signal of a terahertz band according to an example embodiment.

As described above, in a structure for transmitting and receiving a wireless signal of an optical-based terahertz band, the wireless signal may be modulated into a high-speed signal with a high quality using the existing optical technology. However, the structure has disadvantages in a physical size, complexity and power consumption of a wireless signal transmitter for transmitting a wireless signal of an optical-based terahertz band.

To overcome the disadvantages, the present disclosure may provide a structure in which an optical signal generation region 210 and a wireless signal generation region 220 constituting a wireless signal transmitter 200 are spatially separated through an optical link using an optical fiber in a transmission and reception system for transmitting and receiving a wireless signal of a terahertz band, as shown in FIG. 2.

By the above structure, the optical signal generation region 210 that generates a large amount of heat and that occupies a large area may be centralized, and a configuration of the wireless signal generation region 220 may be simplified. In particular, the structure may be useful for applications, for example, a wireless fidelity (Wi-Fi) network in a terahertz band.

A photomixer, for example, a UTC-PD, of the wireless signal generation region 220 may have a relatively low sensitivity instead of having an extremely wide bandwidth, and accordingly an input of relatively high optical power may be required. Thus, the wireless signal generation region 220 may need to input a beating signal having relatively high optical power to the UTC-PD by sufficiently amplifying a light intensity of a beating signal received from the optical signal generation region 210. Optical power of approximately +10 decibel milliwatts (dBm) or higher may need to be input to the UTC-PD.

However, when the beating signal having the relatively high optical power is input to the optical fiber, an optical signal may be distorted due to a nonlinear effect occurring in the optical fiber, and it may be difficult to compensate for such a nonlinear distortion in a postprocessing process. Thus, due to the nonlinear effect, the optical power of the beating signal input to the optical fiber may be inevitably limited.

Accordingly, the wireless signal generation region 220 may amplify the light intensity of the beating signal received through the optical fiber, using an optical amplifier, as shown in FIG. 2. However, since the optical amplifier is a device that is relatively large in a physical size, that generates a relatively large amount of heat and that consumes a relatively large amount of power, it may be desirable not to use the optical amplifier in the wireless signal generation region 220 that generates a wireless signal of a terahertz band. Thus, to simplify the configuration of the wireless signal generation region 220, a method to increase a maximum input optical power of a beating signal input to an optical fiber by reducing the nonlinear effect occurring in the optical fiber may be required.

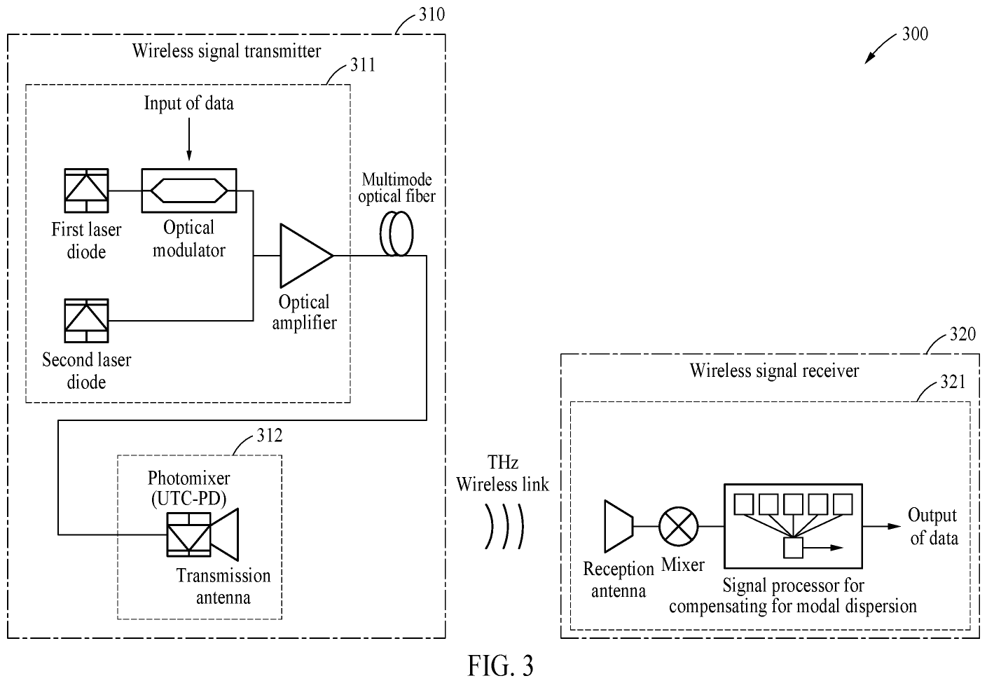

FIG. 3 is a diagram illustrating a transmission and reception system for transmitting and receiving a wireless signal of a terahertz band, including a multimode optical fiber and a signal processor for compensating for a modal dispersion according to an example embodiment.

Referring to FIG. 3, a transmission and reception system 300 for transmitting and receiving a wireless signal of a terahertz band may include a wireless signal transmitter 310 and a wireless signal receiver 320. Here, the wireless signal transmitter 310 may include an optical signal generation region 311 and a wireless signal generation region 312. The optical signal generation region 311 may generate a beating signal by beating two optical signals that have different wavelengths and that are output through different laser diodes. The wireless signal generation region 312 may modulate the beating signal output from the optical signal generation region 311 into a wireless signal with a carrier frequency of a terahertz band, using a photomixer. Also, the wireless signal receiver 320 may include a wireless signal reception region 321. The wireless signal reception region 321 may include a mixer and a signal processor. The mixer may frequency-convert a wireless signal with a carrier frequency of a terahertz band into a baseband signal using a local oscillator (LO) signal received from a LO (not shown). The signal processor may compensate for a modal dispersion of the wireless signal frequency-converted into the baseband signal.

As described above, to simplify a configuration of the wireless signal generation region 312 in the transmission and reception system 300, a method to increase a maximum input optical power of a beating signal input to an optical fiber by reducing a nonlinear effect occurring in the optical fiber may be required.

To this end, the wireless signal transmitter 310 may connect the optical signal generation region 311 and the wireless signal generation region 312 via a multimode optical fiber, thereby reducing the nonlinear effect occurring in the optical fiber.

More specifically, the nonlinear effect may occur in proportion to optical power per unit area within a core through which light actually passes, in the optical fiber. In general, a single-mode optical fiber has a core with a diameter of 8 micrometers (μm) to 10 μm, whereas a multimode optical fiber has a core with a diameter of about 50 μm. Accordingly, when the multimode optical fiber is used, optical power per unit area in the core may be reduced, thereby reducing the nonlinear effect.

In other words, the wireless signal transmitter 310 may reduce the nonlinear effect by connecting the optical signal generation region 311 and the wireless signal generation region 312 via the multimode optical fiber, and thus it is possible to increase optical power of the beating signal input to the optical fiber instead of using a separate optical amplifier.

However, since a modal dispersion occurs in the multimode optical fiber when the multimode optical fiber, instead of a single-mode optical fiber is used, a quality of the beating signal may be reduced. To overcome such a disadvantage, the wireless signal reception region 321 of the wireless signal receiver 320 may include the signal processor to compensate for the modal dispersion caused by the multimode optical fiber. The signal processor for compensating for the modal dispersion may include, for example, a proposed linear equalizer, such as a feed-forward equalizer (FFE) and a decision-feedback equalizer (DFE).

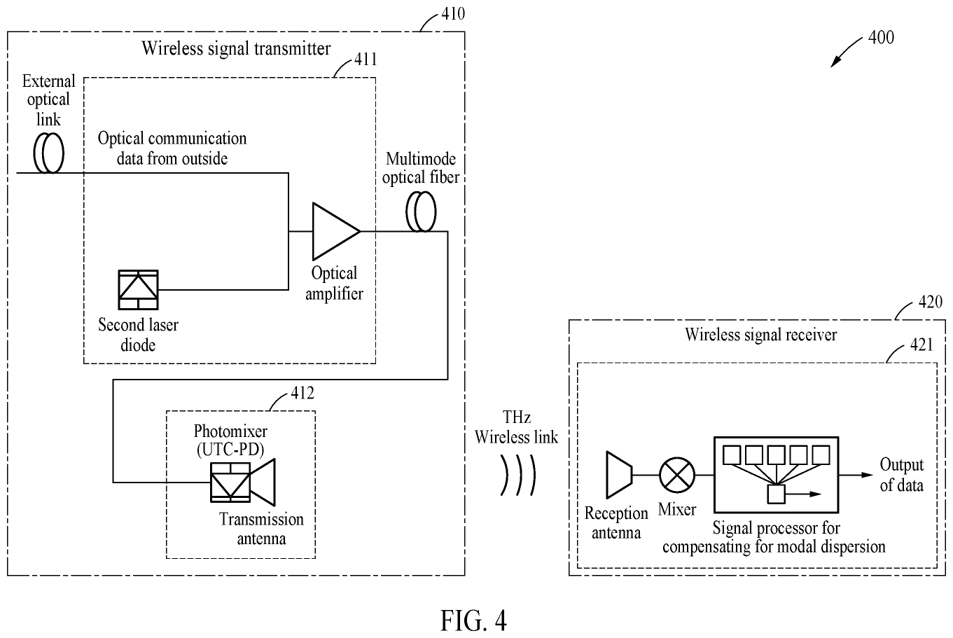

FIG. 4 is a diagram illustrating a transmission and reception system for transmitting and receiving a wireless signal of a terahertz band, connected to an external optical communication system according to an example embodiment.

Referring to FIG. 4, a transmission and reception system 400 for transmitting and receiving a wireless signal of a terahertz band may be used in a terahertz signal transmission and reception structure that is seamlessly connected to the external optical communication system. In an optical signal generation region 411 of a wireless signal transmitter 410 in the transmission and reception system 400, a first laser diode and an optical modulator may be replaced by an optical signal received through an external optical link, unlike FIG. 3.

The optical signal generation region 411 of the wireless signal transmitter 410 may generate a beating signal by beating the optical signal received through the external optical link and an optical signal output through a second laser diode, and may transmit the beating signal to a wireless signal generation region 412 of the wireless signal transmitter 410 through a multimode optical fiber. The wireless signal generation region 412 may modulate the beating signal received from the optical signal generation region 411 using a photomixer, to generate a wireless signal of a terahertz band.

A wireless signal reception region 421 of a wireless signal receiver 420 may frequency-convert a wireless signal with a carrier frequency of a terahertz band into a baseband signal using a mixer, to output data carried on the carrier frequency of the terahertz band. The wireless signal reception region 421 may include a signal processor to compensate for a modal dispersion caused by the multimode optical fiber. The signal processor for compensating for the modal dispersion may include, for example, a proposed linear equalizer, such as an FFE and a DFE.

The method according to example embodiments may be embodied as a program that is executable by a computer and may be implemented as various recording media such as a magnetic storage medium, an optical reading medium, and a digital storage medium. Various techniques described herein may be implemented in digital electronic circuitry, or in computer hardware, firmware, software, or in combinations thereof. The techniques may be implemented as a computer program product, i.e., a computer program tangibly embodied in a machine-readable storage device (for example, a computer-readable medium) or in a propagated signal, for processing by, or to control an operation of, a data processing apparatus, e.g., a programmable processor, a computer, or multiple computers. A computer program, such as the computer program(s) described above, may be written in any form of a programming language, including compiled or interpreted languages, and may be deployed in any form, including as a stand-alone program or as a module, a component, a subroutine, or other units suitable for use in a computing environment. A computer program may be deployed to be processed on one computer or on multiple computers at one site or distributed across multiple sites and interconnected by a communication network.

Processors suitable for processing of a computer program include, by way of example, both general and special purpose microprocessors, and any one or more processors of any kind of digital computer. Generally, a processor will receive instructions and data from a read-only memory or a random-access memory or both. Elements of a computer may include at least one processor for executing instructions and one or more memory devices for storing instructions and data. Generally, a computer also may include, or be operatively coupled to receive data from or transfer data to, or both, one or more mass storage devices for storing data, e.g., magnetic, magneto-optical disks, or optical disks. Examples of information carriers suitable for embodying computer program instructions and data include semiconductor memory devices, e.g., magnetic media such as hard disks, floppy disks, and magnetic tape, optical media such as a compact disk read-only memory (CD-ROM) or digital video disks (DVDs), magneto-optical media such as floptical disks, read-only memory (ROM), random-access memory (RAM), flash memory, erasable programmable ROM (EPROM), or electrically erasable programmable ROM (EEPROM). The processor and the memory may be supplemented by, or incorporated in special purpose logic circuitry.

In addition, non-transitory computer-readable media may be any available media that may be accessed by a computer and may include all computer storage media.

The present specification includes details of a number of specific implements, but it should be understood that the details do not limit any invention or what is claimable in the specification but rather describe features of the specific example embodiment. Features described in the specification in the context of individual example embodiments may be implemented as a combination in a single example embodiment. In contrast, various features described in the specification in the context of a single example embodiment may be implemented in multiple example embodiments individually or in an appropriate sub-combination. Furthermore, the features may operate in a specific combination and may be initially described as claimed in the combination, but one or more features may be excluded from the claimed combination in some cases, and the claimed combination may be changed into a sub-combination or a modification of a sub-combination.

Similarly, even though operations are described in a specific order on the drawings, it should not be understood as the operations needing to be performed in the specific order or in sequence to obtain desired results or as all the operations needing to be performed. In a specific case, multitasking and parallel processing may be advantageous. In addition, it should not be understood as requiring a separation of various apparatus components in the above-described example embodiments in all example embodiments, and it should be understood that the above-described program components and apparatuses may be incorporated into a single software product or may be packaged in multiple software products.

It should be understood that example embodiments disclosed herein are merely illustrative and are not intended to limit the scope of the disclosure. It will be apparent to those skilled in the art that various modifications of the example embodiments may be made without departing from the spirit and scope of the claims and their equivalents.

### EXPLANATION OF REFERENCE NUMERALS

100: Transmission and Reception system for transmitting and receiving wireless signal of terahertz band

110: Wireless signal transmitter

120: Wireless signal receiver

1. A wireless signal transmitter comprising:
two laser diodes configured to output two optical signals having different wavelengths; and
a photomixer configured to modulate a beating signal generated by overlapping of the two optical signals output from the two laser diodes in a space into a wireless signal with a carrier frequency of a terahertz band,
wherein an optical signal generation region comprising the two laser diodes and a wireless signal generation region comprising the photomixer are connected by a multimode optical fiber.

2. The wireless signal transmitter of claim 1, wherein the optical signal generation region further comprises an optical modulator configured to modulate at least one of the two optical signals that have different wavelengths and that are output from the two laser diodes and configured to input data.

3. The wireless signal transmitter of claim 1, wherein the optical signal generation region further comprises an optical amplifier configured to amplify the generated beating signal.

4. A wireless signal transmitter comprising:
a laser diode configured to output an optical signal having a wavelength different from a wavelength of an optical signal received from the outside; and
a photomixer configured to modulate a beating signal generated by overlapping of the optical signal output from the laser diode and the optical signal received from the outside in a space into a wireless signal with a carrier frequency of a terahertz band,
wherein an optical signal generation region comprising the laser diode and a wireless signal generation region comprising the photomixer are connected by a multimode optical fiber.

5. The wireless signal transmitter of claim 4, wherein the optical signal generation region further comprises an optical modulator configured to modulate at least one of the optical signal output from the laser diode and the optical signal received from the outside, and configured to input data.

6. The wireless signal transmitter of claim 4, wherein the optical signal generation region further comprises an optical amplifier configured to amplify the generated beating signal.

7. A wireless signal receiver comprising:
a mixer configured to frequency-convert a wireless signal with a carrier frequency of a terahertz band into a baseband signal using a local oscillator (LO) signal received from a LO; and
a signal processor configured to compensate for a modal dispersion of the wireless signal frequency-converted into the baseband signal,
wherein the modal dispersion is caused by a multimode optical fiber connected between an optical signal generation region and a wireless signal generation region of a wireless signal transmitter configured to output the wireless signal with the carrier frequency of the terahertz band.

8. The wireless signal receiver of claim 7, wherein the signal processor comprises an equalizer configured to compensate for the modal dispersion of the wireless signal frequency-converted into the baseband signal.
